(19) United States
(12) Patent Application Publication
(10) Pub. No.: US 2009/0101402 A1
(43) Pub. Date: Apr. 23, 2009

(54) CIRCUIT BOARD, AND ELECTRONIC DEVICE

(75) Inventors: TAKAO SEKI, TOKYO (JP); HIROYUKI SATOH, TOKYO (JP); HIROAKI TAKEUCHI, TOKYO (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/874,933

(22) Filed: Oct. 19, 2007

(51) Int. Cl. H05K 1/11

(52) U.S. Cl. 174/262

(57) ABSTRACT

A circuit board having a plurality of wiring layers is provided that includes interlayer signal wires that provide an electrical connection between circuit patterns disposed on different wiring layers and ground planes formed in a manner to surround the interlayer signal wire on at least a part of the wiring layers that are penetrated through by the interlayer signal wires. It is desirable that an inner circumference of the ground planes on the wiring layers is a circle centered around the interlayer signal wires. It is further desirable that distances between the ground plane and the interlayer signal wire on each wiring layer on which the ground planes are formed are approximately equal.

### BACKGROUND

1. Technical Field

The present invention relates to a circuit board and an electronic device and, more particularly, the present invention relates to a circuit board that includes a plurality of wiring layers and an electronic device provided with the circuit board and a circuit element.

2. Related Art

As a multilayer board obtained by layering a plurality of boards on which circuit patterns are formed, the multilayer board disclosed in Japanese Patent Application Publication No. 2007-88058 is known, for example. In such a multilayer board, transmission of a signal between the circuits formed on each board is achieved in many cases by an interlayer signal wire formed in a manner to penetrate through the boards. On the other hand, there is a possibility that the signal transmitted on such an interlayer signal wire may interfere with a signal transmitted on another interlayer signal wire or a signal transmitted on a wire of a circuit near the interlayer signal wire.

### SUMMARY

Therefore, it is an object of an aspect of the present invention to provide a circuit board and an electronic device that are capable of overcoming the above drawbacks accompanying the related art. The above and other objects can be achieved by combinations described in the independent claims. The dependent claims define further advantageous and exemplary combinations of the present invention.

According to a first aspect related to the innovations herein, one exemplary apparatus may include a circuit board having a plurality of wiring layers. The circuit board includes interlayer signal wires that provide an electrical connection between circuit patterns disposed on different wiring layers and ground planes formed in a manner to surround the interlayer signal wire on at least a part of the wiring layers that are penetrated through by the interlayer signal wires.

According to a second aspect related to the innovations herein, one exemplary apparatus may include an electronic device that includes a circuit board and a circuit element formed on the circuit board. In the electronic device, the circuit board includes interlayer signal wires that provide an electrical connection between circuit patterns disposed on different wiring layers and ground planes formed in a manner to surround the interlayer signal wire on each wiring layer that is penetrated through by the interlayer signal wires.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 is a cross-sectional view of a circuit board 10 and a motherboard 600.

FIG. 2 is a cross-sectional view of a proximity of an interlayer signal wire 201 of the circuit board 10.

FIG. 3 is a top view of a wiring layer 21 in a proximity of the interlayer signal wire 201 of the circuit board 10.

FIG. 4 is a top view of a wiring layer 25 in a proximity of the interlayer signal wire 201 of the circuit board 10.

FIG. 5 is a top view of the wiring layer 21 in a proximity of the interlayer signal wire 201 of the circuit board 10 where ground planes 171 are formed instead of ground planes 161.

FIG. 6 is a top view of the wiring layer 25 in a proximity of the interlayer signal wire 201 of the circuit board 10 where the ground planes 171 are formed instead of the ground planes 161.

FIG. 7 is a cross-sectional view of a proximity of an interlayer signal wire 202 of the circuit board 10.

FIG. 8 is a cross-sectional view of a proximity of an interlayer signal wire 203 of the circuit board 10.

FIG. 9 is a schematic view showing a positional relationship of coupler wires 551, 552 as seen from a top surface of the circuit board 10.

FIG. 10 is a cross-sectional view of a proximity of a circuit element 502 of the circuit board 10.

### DESCRIPTION OF EXEMPLARY EMBODIMENTS

Hereinafter, an embodiment of the present invention will be described. The embodiment does not limit the invention according to the claims, and all the combinations of the features described in the embodiment are not necessarily essential to means provided by aspects of the invention.

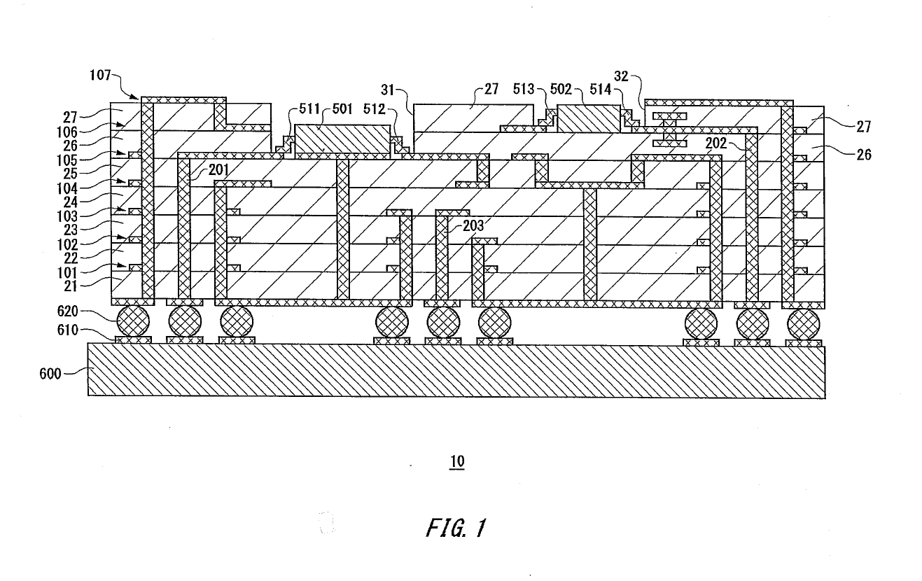

FIG. 1 is a cross-sectional view of a circuit board 10 and a motherboard 600. The circuit board 10 according to the present embodiment may be an SiP (System in Package) module that receives high frequency signals between motherboards 600, for example, and includes a plurality of wiring layers 21˜27 layered sequentially. In the following description, a surface on a lower side of the wiring layer 21 in FIG. 1 is referred to as “a bottom surface of the circuit board 10” and a surface on an upper side of the wiring layer 27 in FIG. 1 is referred to as “a top surface of the circuit board 10.” Furthermore, a surface of each wiring layer 21˜27 facing the bottom surface of the circuit board 10 is referred to as “a bottom surface of the wiring layer 21˜27” and a surface of each wiring layer 21˜27 facing the top surface of the circuit board 10 is referred to as “a top surface of the wiring layer 21˜27.”

Circuit patterns 101˜107 are disposed on the top surface of each wiring layer 21˜27. Each circuit pattern 101˜107 includes a signal line and a ground pattern formed on a top surface of each corresponding wiring layer 21˜27. The circuit board 10 further includes interlayer signal wires 201, 202, 203 that provide an electrical connection between a plurality of circuit patterns among the circuit patterns 101˜107.

Furthermore, an indented portion 31 and an indented portion 32 are formed on the top surface of the circuit board 10 in different locations. The indented portion 31 is formed by cross-sectional surfaces of the wiring layer 26 and the wiring layer 27 exposed by removing a portion of the wiring layer 26 and the wiring layer 27 in a direction of the surface in the same location and the top surface of the wiring layer 25 exposed in the location surrounded by the aforementioned cross-sectional surfaces.

The indented portion 32 is formed by cross-sectional surfaces of the wiring layer 27 exposed by removing a portion of the wiring layer 27 in a direction of the surface in a different location than the indented portion 31 and the top surface of the wiring layer 26 exposed in the location surrounded by the aforementioned cross-sectional surfaces. The indented portion 31 and the indented portion 32 may be formed by performing an etching process on a portion of the wiring layer 26 and the wiring layer 27.

A circuit element 501 is disposed on the top surface of the wiring layer 25 exposed in the indented portion 31 and is electrically connected via terminals 511, 512 to a portion of the circuit pattern 105 also exposed on the top surface of the wiring layer 25. The circuit element 502 is disposed on the top surface of the wiring layer 26 exposed in the indented portion 32 and is electrically connected via terminals 513, 514 to a portion of the circuit pattern 106 also exposed on the top surface of the wiring layer 26. The circuit elements 501, 502 may be active parts such as ICs or LSIs or passive parts such as transistors, resistors, or capacitors.

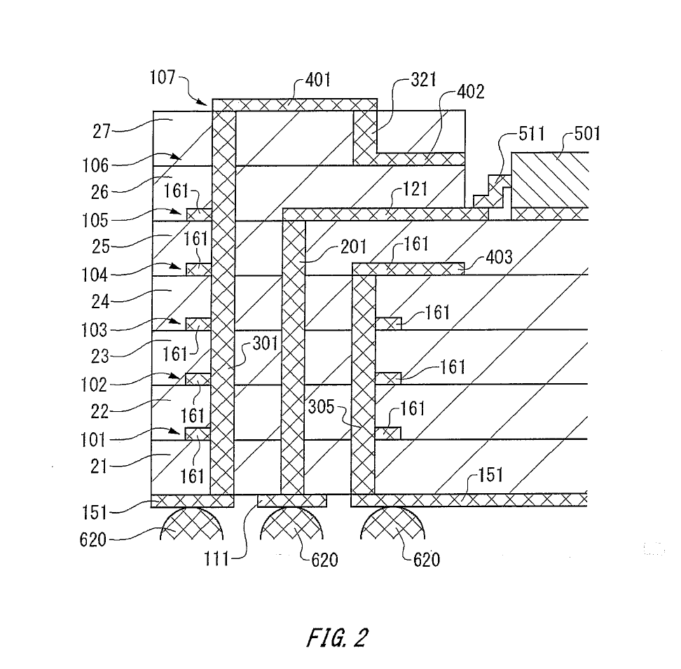

FIG. 2 is a cross-sectional view of a proximity of the interlayer signal wire 201 of the circuit board 10. As shown in FIG. 2, a signal electrode 111 and a ground electrode 151 are formed in the proximity of the interlayer signal wire 201 on the bottom surface of the wiring layer 21. The signal electrode 111 is electrically connected via a terminal ball 620 to at least one electrode 610 from among a plurality of electrodes 610 disposed on the motherboard 600. Furthermore, the signal electrode 111 is electrically connected to a terminal 511 of the circuit element 501 via the interlayer signal wire 201 and a signal line 121.

The ground electrode 151 is electrically connected via the terminal ball 620 to an electrode 610 from among the plurality of electrodes 610 disposed on the motherboard 600 that is different from the electrode 610 to which the signal electrode 111 is connected. Furthermore, the ground electrode 151 is held at a ground potential. A plurality of ground electrodes 151 may be disposed in a range of the signal electrode 111.

The signal line 121 is formed on the top surface of the wiring layer 25. The signal line 121 is electrically connected to the terminal 511 of the circuit element 501. The interlayer signal wire 201 is a conductive transmission path formed in a manner to penetrate through the wiring layers 21˜25 and is electrically connected between the signal electrode 111 and the signal line 121. The signal line 121 is a transmission path that transmits a high frequency signal from the motherboard 600 through the terminal ball 620, the signal electrode 111, and the interlayer signal wire 201, for example.

Ground planes 161 are formed on the top surface of each wiring layer 21˜25. An interlayer ground wire 301 is a conductive transmission path formed in a manner to penetrate through the wiring layers 21˜27 and extends from the ground electrode 151 in a direction parallel to the interlayer signal wire 201. The interlayer ground wire 301 electrically connects the ground planes 161 formed on the top surface of each wiring layer 21˜25 to the ground electrode 151. Furthermore, the interlayer ground wire 301 is disposed in a position such that the direction of extension thereof does not cross the signal line 121 and an upper end of the interlayer ground wire 301 extends farther in a direction of the top surface of the circuit board 10 than an upper end (a portion connected to the signal line 121) of the interlayer signal wire 201 does.

An interlayer ground wire 305 is a conductive transmission path formed in a manner to penetrate through the wiring layers 21˜24 and extends from the ground electrode 151 in a direction parallel to the interlayer signal wire 201. The interlayer ground wire 305 electrically connects the ground planes 161 formed on the top surface of each wiring layer 21˜25 to the ground electrode 151.

Furthermore, the interlayer ground wire 305 is disposed in a position such that the direction of extension thereof does not cross the signal line 121 and an upper end of the interlayer ground wire 305 extends to a layer that is closer to the bottom surface of the circuit board 10 than the wiring layer 25 on which the signal line 121 is formed is. In the present embodiment, the interlayer ground wire 305 extends until the top surface of the wiring layer 24, as shown in FIG. 2. Accordingly, the interlayer ground wire 305 and the signal line 121 are electrically insulated.

A ground pattern 401 is formed on the top surface of the wiring layer 27. The ground pattern 401 is formed above a connection portion at which the upper end of the interlayer signal wire 201 connects to the signal line 121. Furthermore, a ground pattern 402 is formed on the top surface of the wiring layer 26. The ground pattern 402 is formed above the signal line 121 except at a location above the aforementioned connection portion.

The ground patterns 401, 402 are formed parallel to the signal line 121 on the wiring layers 26, 27, which are different wiring layers than the wiring layer 25 on which the signal line 121 is formed. An end of the ground pattern 401 is electrically connected to the upper end of the interlayer ground wire 301. The other end of the ground pattern 401 is electrically connected to the ground pattern 402 via an interlayer wire 321.

In the manner described above, the ground pattern 402 can be formed above the signal line 121 on the wiring layer 26 closer to the signal line 121 in comparison to the ground pattern 401 located above the connection portion of the interlayer signal wire 201 and the signal line 121. In other words, the ground pattern 401 is formed above the connection portion of the signal line 121 in a manner to be facing the connection portion and separated from the signal line 121 by only the two layers of the wiring layers 26, 27 and the ground pattern 402 is formed above the signal line 121 except at the location above the connection portion in a manner to be facing the signal line 121 except at the location of the connection portion and separated from the signal line 121 by only the one layer of the wiring layer 26.

Through the above configuration, a capacitance component arising between the ground pattern 401 and the signal line 121 in the connection portion can be made smaller than a capacitance component arising between the ground pattern 402 and the signal line 121 in a portion other than the connection portion. Furthermore, a ground pattern 403 may be formed below the signal line 121. It is desirable that the ground pattern 403 be formed parallel to the signal line 121 and that an end of the ground pattern 403 be electrically connected to the ground planes 161 and held at a ground potential. In the circuit board 10, the ground patterns 401˜403 may be electrically connected to the ground electrode 151 via an interlayer ground wire, not shown, formed in a manner to penetrate each of the wiring layers 21˜27.

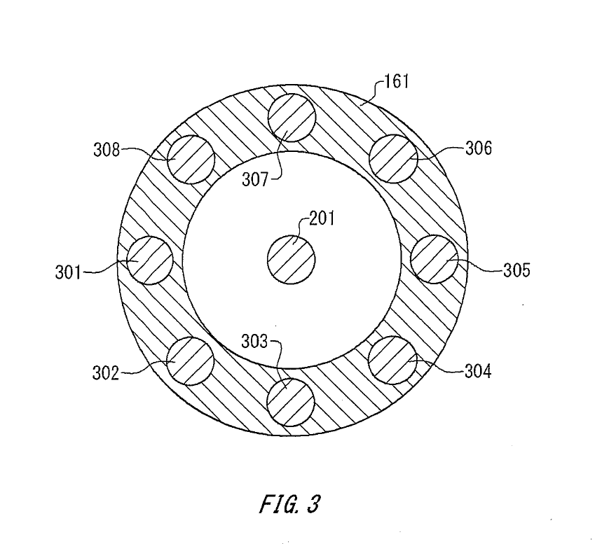

FIG. 3 is a cross-sectional view as seen from above of the wiring layer 21 in a proximity of the interlayer signal wire 201 of the circuit board 10. As shown in FIG. 3, the ground planes 161 formed on the wiring layer 21 are formed to surround the interlayer signal wire 201. Furthermore, the ground planes 161 have a circular inner circumference centered around the interlayer signal wire 201. Accordingly, the distance between the ground planes 161 and the interlayer signal wire 201 is generally uniform.

Through the configuration described above, by forming the ground planes 161 circularly surrounding the periphery of the interlayer signal wire 201 on the top surface of the wiring layer 21, noise of the signal transmitted in the interlayer signal wire 201 is less likely to be passed into a signal line on the circuit pattern 101 or the like. The ground planes 161 formed on the top surface of the wiring layer 21 may be formed on the entire top surface of the wiring layer 21 except the periphery of the interlayer signal wire 201 and other signal wires.

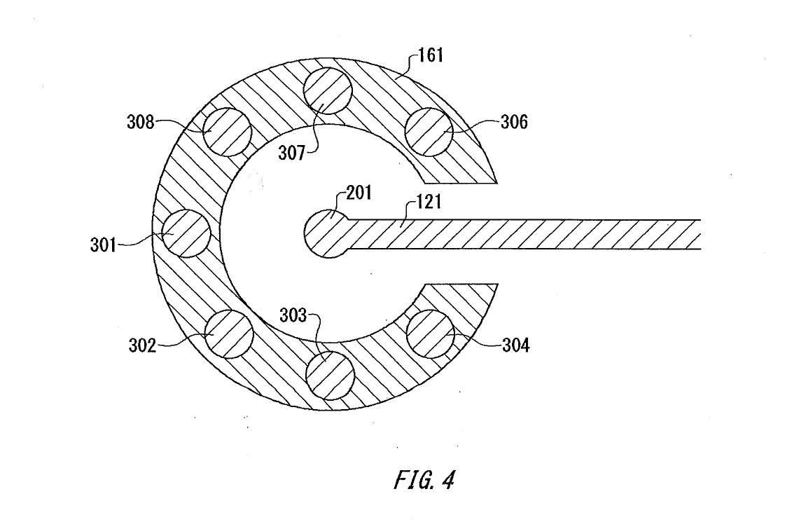

Furthermore, the ground planes 161 surrounding the periphery of the interlayer signal wire 201 are also formed on the top surface of each wiring layer 22˜25. Accordingly, the noise of the signal transmitted in the interlayer signal wire 201 is less likely to be passed into the signal line on the circuit patterns 102˜105. The ground planes 161 formed on the top surface of the wiring layers 22˜24 may be formed on the entire top surface of the wiring layers 22˜24 except a periphery of the interlayer signal wire 201 and other signal wires. In such a case, the ground planes 161 formed on the top surface of the wiring layer 24 may include the ground pattern 403. Furthermore, as shown in FIG. 4, ground planes 165 formed on the top surface of the wiring layer 25 is formed in a manner to surround the periphery of the interlayer signal wire 201 except for an area on both sides of the signal line 121.

Furthermore, the ground planes 161 formed on the top surface of each wiring layer 21˜25 are electrically connected to the eight interlayer ground wires 301˜308 including the interlayer ground wires 301, 305 shown in FIG. 2. The interlayer ground wires 301˜308 each electrically connect the ground planes 161 and the ground electrode 151. The number of interlayer ground wires arranged corresponding to the interlayer signal wire 201 is not limited to eight as in the present embodiment and may be increased to lessen the potential difference between the ground planes 161 and the ground electrode 151.

In the manner described above, the transmission line that includes the interlayer signal wire 201 and the signal line 121 is shielded by the plurality of ground planes 161, the interlayer ground wires 301˜308, and the ground patterns 401˜403 disposed in a proximity of the transmission line. Therefore, the noise of the signal transmitted in the transmission line that includes the interlayer signal wire 201 and the signal line 121 is less likely to be passed into the signal lines on the circuit patterns 101˜107 or the like.

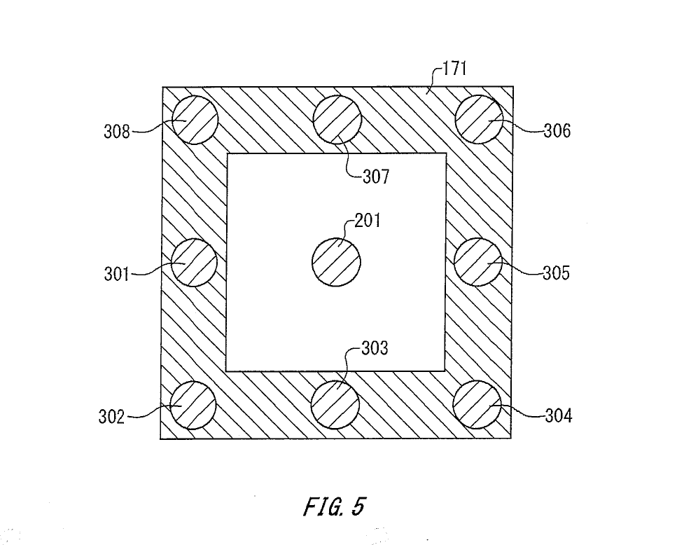

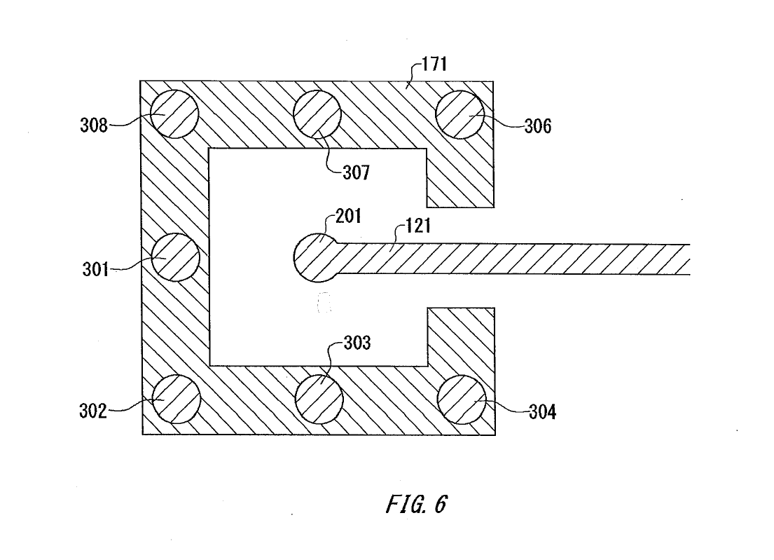

In the circuit board 10, ground planes 171 shown in FIG. 5 may be formed around the periphery of the interlayer signal wire 201 on the top surfaces of the wiring layers 21˜24 instead of the ground planes 161 shown in FIG. 3. Furthermore, ground planes 171 shown in FIG. 6 may be formed around the periphery of the interlayer signal wire 201 on the top surface of the wiring layer 25 instead of the ground planes 161 shown in FIG. 4. As shown in FIG. 5 and FIG. 6, the ground planes 171 are formed to surround the interlayer signal wire 201 in the same manner as the ground planes 161 but are different from the ground planes 161 in that the ground planes 171 have a square-shaped inner circumference centered on a diagonal line of the interlayer signal wire 201.

By forming the ground planes 171 described above on the top surface of each wiring layer 21˜25 of the circuit board 10, the noise of the signal transmitted in the interlayer signal wire 201 is less likely to be passed into the signal lines on the circuit patterns 101˜105 or the like. Furthermore, a capacitance component arising between the interlayer signal wire 201 and the ground planes 171 can be made smaller than the capacitance component arising between the interlayer signal wire 201 and the ground planes 161.

In a case where the ground planes 171 are formed on the top surface of each wiring layer 21˜25 of the circuit board 10, a plurality of ground electrodes 151 may be disposed on a bottom surface of the circuit board 10, including locations corresponding to the interlayer ground wires 301˜308 on sides of the square shape surrounding the signal electrode 111.

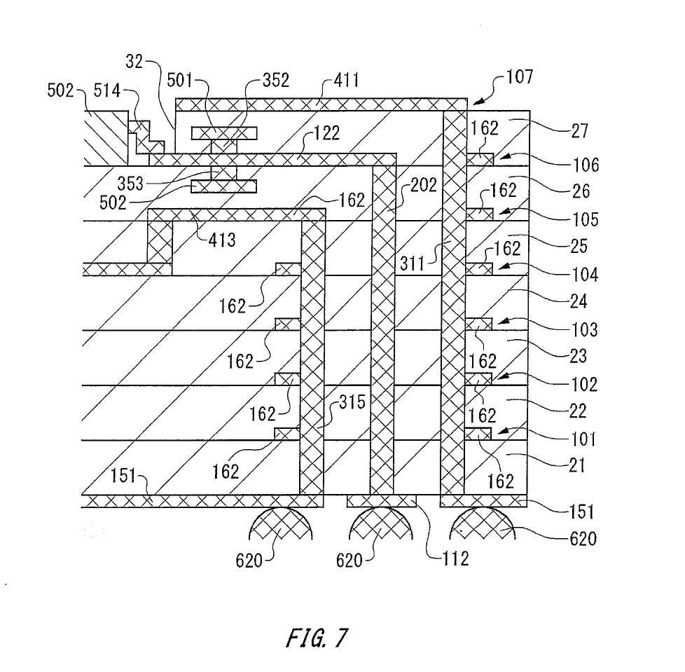

FIG. 7 is a cross-sectional view of a proximity of the interlayer signal wire 202 of the circuit board 10. In FIG. 7, configurations that are the same as those described referencing FIG. 2 are given the same numbering and the description is partially omitted. As shown in FIG. 7, a signal electrode 112 and the ground electrode 151 are formed on the bottom surface of the wiring layer 21 in a proximity of the interlayer signal wire 202. The signal electrode 112 is electrically connected via the terminal ball 620 to at least one electrode 610 from among the plurality of electrodes 610 disposed on the motherboard 600.

The signal line 122 is formed on the top surface of the wiring layer 26. The signal line 122 is electrically connected to a terminal 514 of the circuit element 502. The interlayer signal wire 202 is formed in a manner to penetrate through the wiring layers 21˜26 and is electrically connected between the signal electrode 112 and the signal line 122. The signal line 122 is a transmission path that transmits a high frequency signal from the motherboard 600 or a high frequency signal to the motherboard 600 through the terminal ball 620, the signal electrode 112, and the interlayer signal wire 202, for example.

Ground planes 162 are formed on the top surface of each wiring layer 21˜26. Each ground plane 162 has a shape identical to the ground plane 161 and circularly surrounds the periphery of the interlayer signal wire 202. The ground planes 171 may be formed on the top surfaces of the wiring layers 21˜26 instead of the ground planes 162. An interlayer ground wire 311 is formed in a manner to penetrate through the wiring layers 21˜27 and extends from the ground electrode 151 in a direction parallel to the interlayer signal wire 202. The interlayer ground wire 311 electrically connects the ground planes 162 formed on the top surface of each wiring layer 21˜26 to the ground electrode 151. Furthermore, the interlayer ground wire 311 is disposed in a position such that the direction of extension thereof does not cross the signal line 122 and an upper end of the interlayer ground wire 311 extends farther in a direction of the top surface of the circuit board 10 than an upper end of the interlayer signal wire 202.

An interlayer ground wire 315 is formed in a manner to penetrate through the wiring layers 21˜25 and extends from the ground electrode 151 in a direction parallel to the interlayer signal wire 202. The interlayer ground wire 315 electrically connects the ground planes 162 formed on the top surface of each wiring layer 21˜24 to the ground electrode 151. Furthermore, the interlayer ground wire 315 is disposed in a position such that the direction of extension thereof does not cross the signal line 122 and an upper end of the interlayer ground wire 315 extends to a layer that is closer to the bottom surface of the circuit board 10 than the wiring layer 26 on which the signal line 122 is formed is. In the present embodiment, the interlayer ground wire 315 extends until the top surface of the wiring layer 25, as shown in FIG. 7. Accordingly, the interlayer ground wire 315 and the signal line 122 are electrically insulated.

In the same manner as the interlayer signal wire 201, a plurality of interlayer ground wires (eight, for example) including the interlayer ground wires 311, 315 is disposed in a periphery of the interlayer signal wire 202. Each interlayer ground wire in the plurality of interlayer ground wires electrically connects the ground planes 162 and the ground electrode 151.

A ground pattern 411 is formed on the top surface of the wiring layer 27. The ground pattern 411 is formed above the signal line 122 parallel to the signal line 122 and an end of the ground pattern 411 is electrically connected to an upper end of the interlayer ground wire 311. Furthermore, a ground pattern 413 may be formed below the signal line 122. In the present embodiment, the ground pattern 413 is formed on the top surface of the wiring layer 25. The ground pattern 413 is formed parallel to the signal line 122 and an end of the ground pattern 413 is electrically connected to the ground planes 162 and held at a ground potential.

In the manner described above, the circuit board 10 includes the ground pattern 411 and the ground pattern 413 formed parallel to the signal line 122 on the wiring layer 25 and the wiring layer 27 of both sides sandwiching the wiring layer 26 on which the signal line 122 is formed. The circuit board 10 further includes an electrode 501 disposed between the signal line 122 and the ground pattern 411 and electrically connected to the signal line 122 via the interlayer wire 352 and an electrode 502 disposed between the signal line 122 and the ground pattern 413 and electrically connected to the signal line 122 via the interlayer wire 353.

By including the electrode 501 and the electrode 502 described above, capacitors having a prescribed capacitance can be disposed between the signal line 122 and the ground pattern 411 and between the signal line 122 and the ground pattern 413. For example, the capacitors can be used for a low-pass filter (RC integration circuit) or the like. In the circuit board 10, the ground patterns 411, 413 may be electrically connected to the ground electrode 151 via the interlayer ground wire, not shown, formed in a manner to penetrate through each of the wiring layers 21˜27.

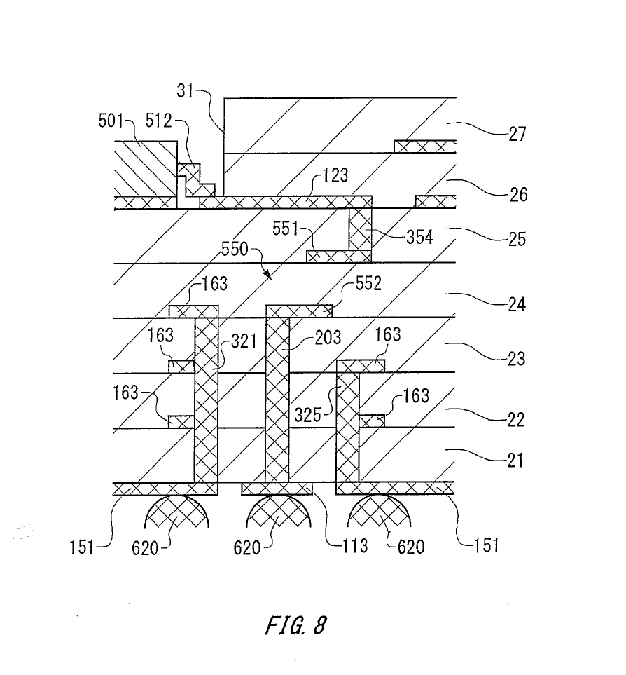

FIG. 8 is a cross-sectional view of a proximity of the interlayer signal wire 203 of the circuit board 10. In FIG. 8, configurations that are the same as those described referencing FIG. 2 are given the same numbering and the description is partially omitted. As shown in FIG. 8, a signal electrode 113 and the ground electrode 151 are formed on the bottom surface of the wiring layer 21 in a proximity of the interlayer signal wire 203. The signal electrode 113 is electrically connected via the terminal ball 620 to at least one electrode 610 from among the plurality of electrodes 610 disposed on the motherboard 600 and is also electrically connected to an end of the interlayer signal wire 203.

Ground planes 163 are formed on the top surface of each wiring layer 21˜23. Each ground plane 163 has a shape identical to the ground planes 161, 162 and circularly surrounds the periphery of the interlayer signal wire 203. The ground planes 171 may be formed on the top surfaces of the wiring layers 21˜23 instead of the ground planes 163.

An interlayer ground wire 321 is formed in a manner to penetrate through the wiring layers 21˜23 and extends from the ground electrode 151 in a direction parallel to the interlayer signal wire 203. The interlayer ground wire 321 electrically connects the ground planes 163 formed on the top surface of each wiring layer 21˜23 to the ground electrode 151. An interlayer ground wire 325 is formed in a manner to penetrate through the wiring layers 21, 22 and extends from the ground electrode 151 in a direction parallel to the interlayer signal wire 203. The interlayer ground wire 325 electrically connects the ground planes 163 formed on the top surface of the wiring layers 21, 22 to the ground electrode 151.

In the same manner as the interlayer signal wires 201, 202, a plurality of interlayer ground wires (eight, for example) including the interlayer ground wires 321, 325 is disposed in a periphery of the interlayer signal wire 203. Each interlayer ground wire in the plurality of interlayer ground wires electrically connects the ground planes 163 and the ground electrode 151.

A signal line 123 is formed on the top surface of the wiring layer 25. The signal line 123 electrically connects the terminal 512 of the circuit element 501 to the interlayer wire 354 formed in a manner to penetrate through the wiring layer 25. A coupler wire 552 is formed on the top surface of the wiring layer 23 and a coupler wire 551 is formed on the top surface of the wiring layer 24 adjacent to the wiring layer 23. The coupler wires 551, 552 form a coupler 550.

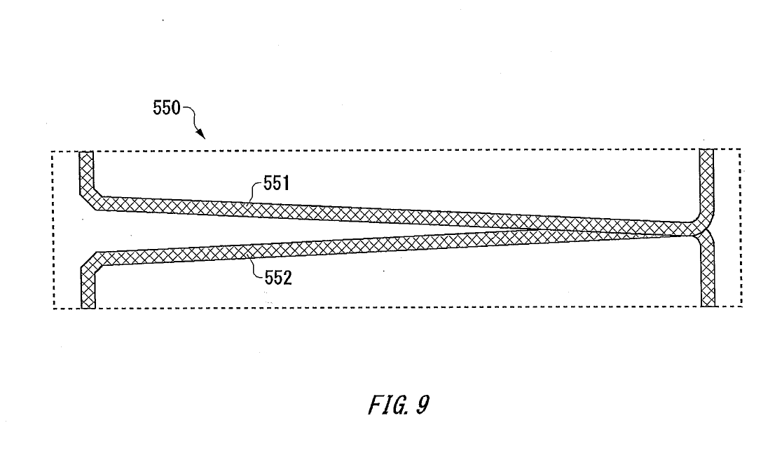

FIG. 9 is a schematic view showing a positional relationship of the coupler wires 551, 552 as seen from the top surface of the circuit board 10. The two coupler wires 551, 552 in the coupler 550 are formed in a manner to sandwich the wiring layer 24 and include portions that face each other across the width of the wiring layer 24. Furthermore, all portions of the coupler wire 551, including the portion facing the coupler wire 552, are insulated from all portions of the coupler wire 552, including the portion facing the coupler wire 551.

A first end of the coupler wire 551 (for example, a line end in the upper right portion of FIG. 9) is electrically connected to the interlayer wire 354. Furthermore, the other end of the coupler wire 551 (for example, a line end in the upper left portion of FIG. 9) is electrically connected to a signal line, not shown, formed on the top surface of the wiring layer 24. A first end of the coupler wire 552 (for example, a line end in the lower right portion of FIG. 9) is electrically connected to the interlayer signal wire 203. Furthermore, the other end of the coupler wire 552 (for example, a line end in the lower left portion of FIG. 9) is electrically connected to a signal line, not shown, formed on the top surface of the wiring layer 23.

In the coupler 550 including the coupler wire 551 and the coupler wire 552 described above, in a case where a signal is transmitted on the coupler wire 552 from the first end thereof to the other end thereof, an intensity correlation signal of the signal arises in the coupler wire 551 because of magnetic coupling. The intensity correlation signal is output from the first end of the coupler wire 551.

Accordingly, where a signal is supplied to the coupler wire 552 in the coupler 550 from the electrode 610 disposed on the motherboard 600 via the terminal ball 620, the signal electrode 113, and the interlayer signal wire 203, for example, the intensity correlation signal of the signal is supplied to the terminal 512 of the circuit element 501 via the interlayer wire 354 and the signal line 123.

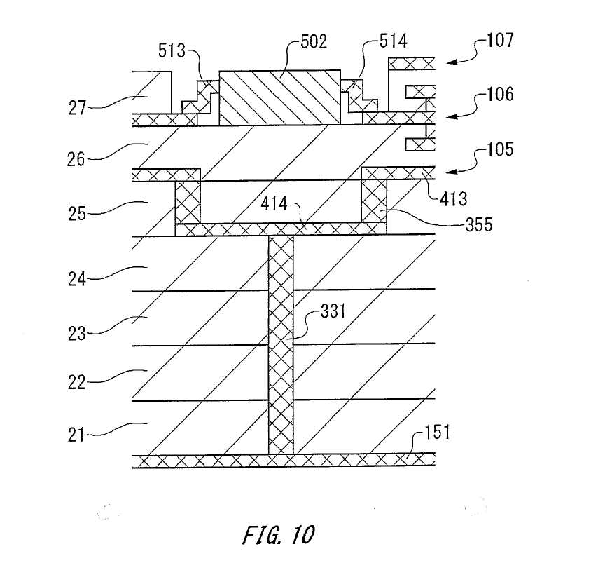

FIG. 10 is a cross-sectional view of a proximity of a circuit element 502 of the circuit board 10. In FIG. 10, configurations that are the same as those described referencing FIG. 2 are given the same numbering and the description is partially omitted. In the same manner as described above, the circuit element 502 is disposed on the top surface of the wiring layer 26. The circuit pattern 106 is also disposed on the top surface of the wiring layer 26 and is electrically connected to the terminals 513, 514 of the circuit element 502.

The ground pattern 413 is formed parallel to the signal line 122 of the circuit pattern 106 on the top surface of the wiring layer 25, which is different from the wiring layer 26 on which the circuit pattern 106 is disposed. Furthermore, a ground pattern 414 is formed on the top surface of the wiring layer 24, which is farther from the circuit element 502 than the wiring layer 25 on which the ground pattern 413 is formed is, in a manner to face the lower surface of the circuit element 502. The ground pattern 414 is electrically connected to the ground pattern 413 via the interlayer wire 355 formed in a manner to penetrate through the wiring layer 25. Accordingly, by holding the ground pattern 413 at the ground potential as described above, the ground pattern 414 is also held at the ground potential. The ground pattern 414 may be electrically connected to the ground electrode 151 via the interlayer ground wire 331 formed in a manner to penetrate through the wiring layers 21˜24.

In the manner described above, the capacitance component arising between the ground pattern 414 and the circuit element 502 or the terminals 513, 514 of the circuit element 502 can be decreased by separating the ground pattern 414, formed at a location facing the bottom surface of the circuit element 502, farther from the circuit element 502 than from the ground pattern 413 formed at a location other than the aforementioned location.

Furthermore, in the circuit pattern 106, in a case where a signal line in proximity to a connection point at which the terminals 513, 514 of the circuit element 502 are electrically connected is smaller than a portion outside the connection point, an inductive component of the signal line at the connection point increases. Here, the capacitance component arising between the circuit element 502 and the ground pattern 414 is cancelled out by the inductive component, so that the impedance from the signal line 122 to the circuit element 502 can be kept uniform.

In the circuit board 10 described above, the interlayer signal wires 201˜203, the interlayer ground wires 301˜308, 311, 315, 321, 325, 331, and the interlayer wires 351˜355 may be vias penetrating through the wiring layers, for example. The circuit board 10 may be, for example, an SiP obtained by modularizing a plurality of electronic parts such as semiconductor chips. Furthermore, the circuit board 10 may itself be a printed circuit board equipped with the plurality of electronic parts.

While the circuit board 10 has been described as an embodiment of the present invention, the technical scope of the invention is not limited to the above described embodiment. It is apparent to persons skilled in the art that various alterations and improvements can be added to the above-described embodiment. It is also apparent from the scope of the claims that the embodiments added with such alterations or improvements can be included in the technical scope of the invention.

As made clear from the above description, through an embodiment of the present invention, a circuit board including a plurality of wiring layers and an electronic device provided with the circuit board and a circuit element can be realized.

What is claimed is:

1. A circuit board having a plurality of wiring layers, comprising:
interlayer signal wires that provide an electrical connection between circuit patterns disposed on different wiring layers; and
ground planes formed in a manner to surround the interlayer signal wire on at least a part of the wiring layers that are penetrated through by the interlayer signal wires.

2. The circuit board according to claim 1, wherein an inner circumference of the ground plane on the wiring layer is a circle centered around the interlayer signal wires.

3. The circuit board according to claim 2, wherein distances between the ground plane and the interlayer signal wire on each wiring layer on which the ground plane is formed are approximately equal.

4. The circuit board according to claim 1, further comprising an interlayer ground wire that electrically connects the ground planes formed on the different wiring layers.

5. The circuit board according to claim 4, wherein a lower end of the interlayer ground wire is electrically connected to a ground electrode disposed on a bottom surface of the circuit board and the interlayer ground wire extends from the ground electrode in a manner parallel to the interlayer signal wires.

6. The circuit board according to claim 5, further comprising signal electrodes disposed on the bottom surface of the circuit board and connected to a lower end of the interlayer signal wires, wherein:
a plurality of ground electrodes are disposed on the bottom surface of the circuit board on sides of a square surrounding the signal electrodes; and
the inner periphery of the ground planes on the wiring layers is a square shape that surrounds the interlayer signal wires.

7. The circuit board according to claim 5, further comprising a plurality of interlayer ground wires corresponding to one of the interlayer signal wires, wherein at least one of the interlayer ground wires from among the plurality of interlayer ground wires corresponding to the one interlayer signal wire extends until a point that is closer to the lower surface of the circuit board than an upper end of the one interlayer signal wire is.

8. The circuit board according to claim 7, wherein:
the upper end of the one interlayer signal wire is electrically connected to the circuit pattern;
a first interlayer ground wire, which is from among the plurality of interlayer ground wires corresponding to the one interlayer signal wire and extends until a point that is closer to the bottom surface of the circuit board than the circuit pattern is, extends until a point that is closer to the bottom surface of the circuit board than the wiring layer on which the circuit pattern is disposed is.

9. The circuit board according to claim 8, wherein at least one of the interlayer ground wires from among the plurality of interlayer ground wires corresponding to the one interlayer signal wire extends to a point that is closer to the top surface of the circuit board than the upper end of the one interlayer signal wire is.

10. The circuit board according to claim 9, wherein a second interlayer ground wire, which is from among the plurality of interlayer ground wires corresponding to the one interlayer signal wire and disposed on a side opposite to the first interlayer ground wire in relation to the interlayer signal wire, extends to a point that is closer to the top surface of the circuit board than the wiring layer on which the circuit pattern is disposed is.

11. The circuit board according to claim 10, further comprising:
a first ground pattern that is formed parallel to the circuit pattern on the wiring layer that is different from the wiring layer on which the circuit pattern is formed and has one end thereof electrically connected to an upper end of the second interlayer ground wire; and
a second ground pattern that is formed parallel to the circuit pattern on the wiring layer that is closer to the circuit pattern than the first ground pattern is and is electrically connected to another end of the first ground pattern.

12. The circuit board according to claim 1, further comprising:
a circuit element that is formed on the same wiring layer on which the circuit pattern is disposed and is electrically connected to the circuit pattern;
a third ground pattern that is formed parallel to the circuit pattern on the wiring layer that is different from the wiring layer on which the circuit pattern is disposed; and
a fourth ground pattern that is formed on the wiring layer that is farther from the circuit element than the wiring layer on which the third ground pattern is formed is and is electrically connected to the third ground pattern.

13. The circuit board according to claim 1, further comprising:
a signal electrode disposed on the bottom surface of the circuit board and electrically connected to a lower end of one interlayer signal wire;
a first coupling wire formed on one of the wiring layers; and
a second coupling wire formed on the wiring layer adjacent to the one wiring layer, wherein the first coupling wire receives a signal from the signal electrode via the one interlayer signal wire and the second coupling wire receives from the first coupling wire at least a portion of the signal received by the first coupling wire and outputs the received portion of the signal via the interlayer signal wire that is different from the one interlayer signal wire.

14. The circuit board according to claim 1, further comprising:
a ground pattern formed parallel to the circuit patterns on each wiring layer sandwiching the wiring layer on which the circuit pattern is disposed;
a first electrode disposed between the circuit pattern and one of the ground patterns and electrically connected to the circuit pattern; and
a second electrode disposed between the circuit pattern and the other ground pattern and electrically connected to the circuit pattern.

15. An electronic device comprising a circuit board and a circuit element formed on the circuit board, wherein the circuit board includes:
interlayer signal wires that provide an electrical connection between circuit patterns disposed on different wiring layers; and
ground planes formed in a manner to surround the interlayer signal wire on each wiring layer that is penetrated through by the interlayer signal wires.
